(19) United States
(12) Patent Application Publication
(10) Pub. No.: US 2008/0253064 A1
(43) Pub. Date: Oct. 16, 2008

(54) SUPPORTING FRAME FOR DIODES

(76) Inventor: Tse-Pin WU, Sijhih City (TW)

Correspondence Address: SINORICA, LLC, 528 FALLSGROVE DRIVE, ROCKVILLE, MD, 20850, US

(21) Appl. No.: 11/733,223

(22) Filed: Apr. 10, 2007

(51) Int. Cl. H05K 5/00

(52) U.S. Cl. 361/679

(57) ABSTRACT

A structure of a supporting frame made from an electric conductive metal sheet and having a plurality of continuous check like supporting units laid out in a plane, the supporting units are neighboring with other supporting units in vertical and horizontal directions, each supporting unit has a peripheral frame and has at the center thereof two separated semicircular contact ends which have a pair of connecting legs extending to the peripheral frame in mutual contrary directions; each peripheral frame is formed two cuts at two positions in the middles of two frame edges in opposition to the connecting legs which extend to the peripheral frame; the two contact ends are injection formed thereon an insulated seat, the seat has two insulated supporting strips extending linearly from it to the two cuts in the middles of the two frame edges.

### BACKGROUND OF THE INVENTION

1. Field of the invention

The present invention relates to a structure of a supporting frame, and especially to a brand new structure of a supporting frame for diodes for manufacturing the diodes such as LED (light emitting diodes).

2. Description of the Prior Art

In manufacturing diodes, an electric conductive metal sheet is used to make a plurality of continuous check like supporting units, each check has therein contact ends and connecting legs, and then the contact ends are injection formed thereon an insulated seat or are formed thereon an insulated sealing cover.

FIG. 1 shows a conventional supporting frame formed from a plurality of continuous check like portions 90; each check like portion 90 has a peripheral frame 91, and has at the center thereof two separated contact ends 92 which have a pair of connecting legs 93 extending to the peripheral frame 91 in mutual contrary directions. In order to provide supporting force during the process of injection forming the insulated seat or forming the insulated sealing cover on the contact ends 92, a plurality of supporting strips 94 are formed respectively at the contact ends 92 extending in two extending directions respectively orthogonal to those the two connecting legs 93.

Referring to FIG. 2, the supporting frame is used for manufacturing high efficient LEDs (light emitting diodes), each check like portion 90 is injection formed thereon an insulated seat 95 for mounting therein a heat sinking member and a light emitting diode, and then the insulated seat 95 is formed thereon a transparent insulated sealing cover 96.

Such an electric conductive conventional supporting frame will have the following problems during manufacturing diodes:
1. In completion of manufacturing the diodes, by the fact that the supporting strips 94 made of metal are electric conductive, each diode made must be removed from the supporting frame for testing, because the diodes are unable to be tested on the supporting frame, this will render the testing work time and hour consumptive.
2. By providing the supporting strips 94, the insulated seat 95 or the insulated sealing cover 96 on the contact ends 92 is subjected to inability of passing the test with ink, because gaps may be created on the insulated seat 95 or the transparent insulated sealing cover 96 after detachment (removing).
3. The two connecting legs 93 in each check are same in shape, so that they are difficult for discriminating the positive and negative poles, this is subjected to making wrong input of electric power.

The above stated are the main defects of the conventional supporting frame, and improvement is required.

### SUMMARY OF THE INVENTION

In view of the above defects of the conventional supporting frame for diodes, the inventor of the present invention designed a brand new structure of a supporting frame for diodes, the supporting frame is made from an electric conductive metal sheet, and has a plurality of continuous check like supporting units, which check like supporting units are neighboring with other check like supporting units in vertical and horizontal directions, each check like supporting unit has a peripheral frame, and has at the center thereof two separated semicircular contact ends which have a pair of connecting legs extending to the peripheral frame in mutual contrary directions; each peripheral frame is formed two cuts at two positions in the middles of two frame edges in opposition to the connecting legs which extend to the peripheral frame. The two semicircular contact ends are injection formed thereon an insulated seat, the insulated seat has two insulated supporting strips extending linearly therefrom to the two cuts in the middles of the two frame edges mentioned above.

Thereby, the main object of the present invention is to provide a supporting frame for diodes, by virtue that the supporting strips are injection formed of insulated material, when in testing the diodes, it needs only to cut connecting legs from the peripheral frame, the testing work on each diode can be done fast on the supporting frame.

Another object of the present invention is to provide a supporting frame for diodes, wherein the supporting strips at the contact ends are made of insulated material, when the supporting strips is cut from the injection formed insulated seat, no gap will be created on the insulated seat, the insulated seat can pass the test with ink.

A further object of the present invention is to provide a supporting frame for diodes, wherein the two connecting legs in each check like supporting unit are different in shape or at least one of them has a mark indicating a round hole, so that the positive and negative poles of the diode made can be evidently shown, and no wrong input of electric power will occur.

The present invention will be apparent in its features and functions after reading the detailed description of the preferred embodiment thereof in reference to the accompanying drawings.

### BRIEF DESCRIPTION OF THE DRAWINGS

FIG. 1 is a perspective view showing the appearance of a conventional supporting frame for diodes;

FIG. 2 is a schematic perspective view showing the supporting frame in FIG. 1 for manufacturing diodes;

FIG. 3 is a perspective view showing the appearance of the present invention;

FIG. 4 is a schematic perspective view showing the present invention for manufacturing diodes;

FIG. 5 is a schematic view showing the present invention for manufacturing light emitting diodes;

FIG. 6 is a schematic view showing the testing work after manufacturing light emitting diodes in the present invention.

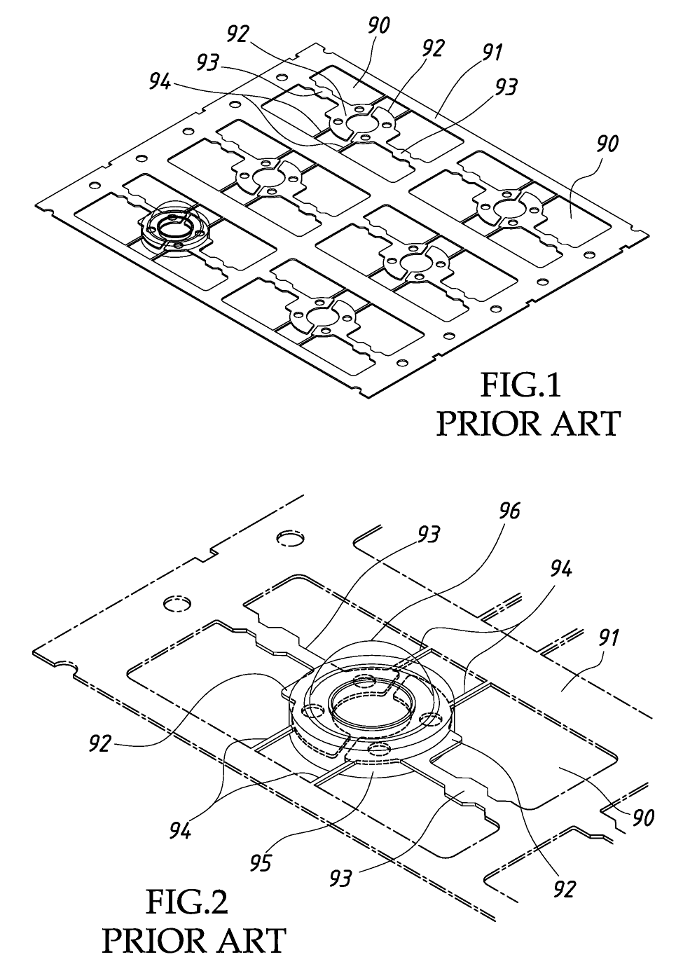

### DETAILED DESCRIPTION OF THE PREFERRED EMBODIMENT

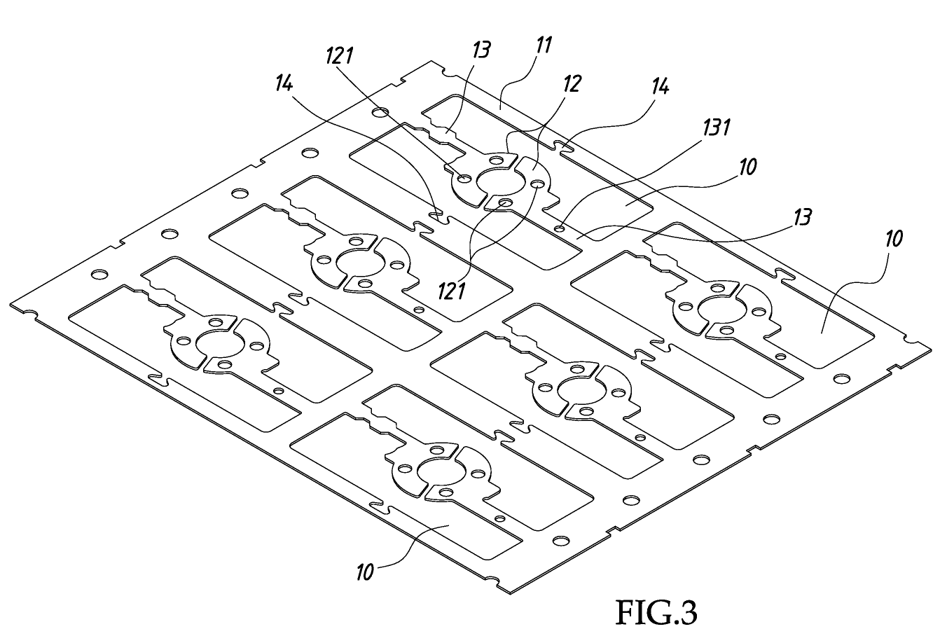

Referring to FIG. 3, the supporting frame for diodes of the present invention is made from an electric conductive metal sheet, and has a plurality of continuous check like supporting units 10 laid out in a plane, which check like supporting units 10 are neighboring with other check like supporting units 10 in vertical and horizontal directions; in the drawing, the check like supporting units 10 are in rectangular shapes but are not limited to the rectangular shapes of course.

Each check like supporting unit 10 has a peripheral frame 11, and has at the center thereof two separated semicircular contact ends 12 which have a pair of connecting legs 13 extending from here to the peripheral frame in mutual contrary directions, the connecting legs 13 extend to shorter frame edges of their corresponding rectangle. The two connecting legs 13 are different in shape or at least one of them has a mark 131 indicating a round hole. The semicircular contact ends 12 are provided thereon with a plurality of round holes 121 to increase holding force.

And each peripheral frame 11 of the check like supporting unit 10 is formed two cuts 14 at two positions in the middles of two frame edges in opposition to the connecting legs 13 which extend to the peripheral frame 11. The two cuts 14 are provided on the longer edges of the rectangular check like supporting unit 10.

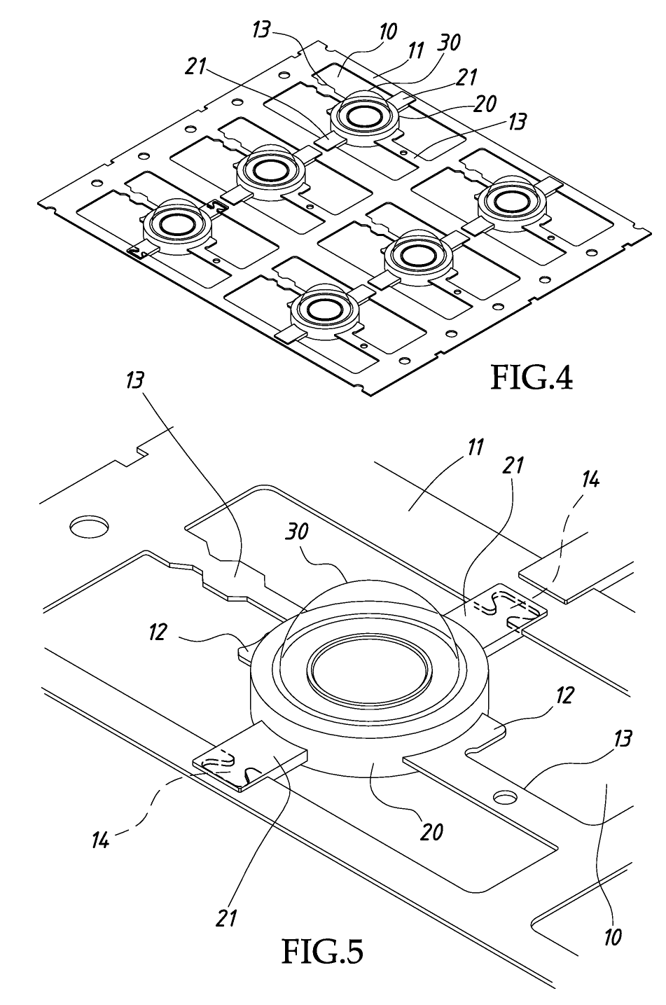

Referring to FIGS. 4 and 5 showing an example of manufacturing high efficient light emitting diodes on a supporting frame, an insulated seat 20 is injection formed in the first place on the two semicircular contact ends 12 in each check like supporting unit 10, and during injection forming the insulated seat 20, two insulated supporting strips 21 extending linearly from the insulated seat 20 to the two cuts 14 in the middles of the two frame edges 11 are formed in the mean time. Then a heat sinking member and a light emitting diode are mounted in the insulated seat 20 (not shown), and the insulated seat 20 is formed thereon a transparent insulated sealing cover 30, and manufacturing of the diode is completed.

The structure of a supporting frame provided by the present invention is same as that of the conventional one in its process of manufacturing, but it only needs to add portions with the shapes of the insulated supporting strips 21 on a die for manufacturing.

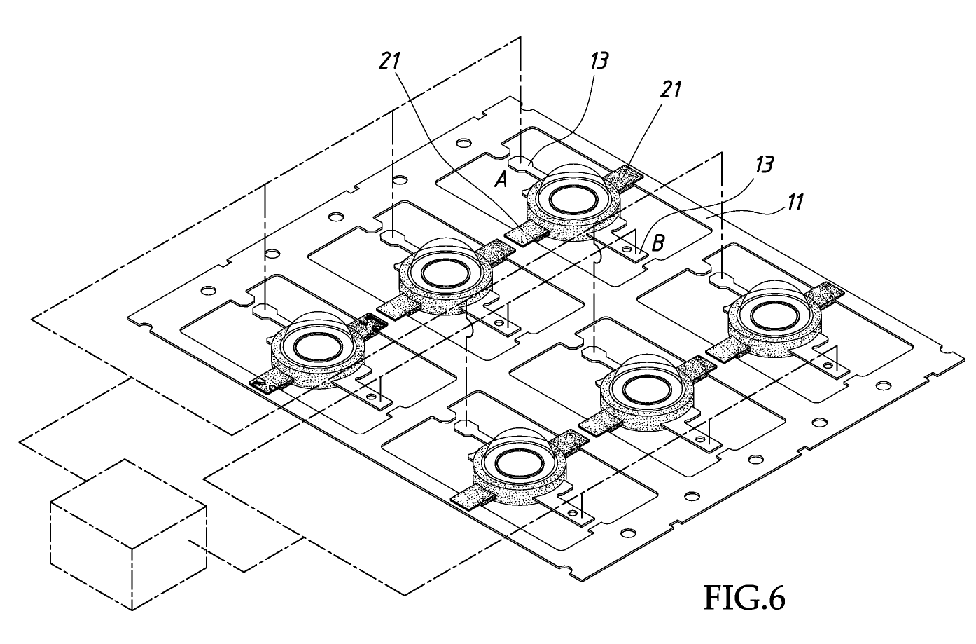

Referring to FIG. 6, when manufacturing of a light emitting diodes is completed, the diodes do not need to be detached from the supporting frame, but it needs only to cut the connecting legs 13 in each check like supporting unit 10 from the peripheral frame 11 (as shown by the positions A and B marked in the drawing), by the supporting force of the insulated supporting strips 21, the testing work on each diode can be done with electric power on the supporting frame to largely lower the testing work time and hour.

And more, by virtue that the connecting legs 13 in each check like supporting unit 10 are different in shape or at least one of them has a mark 131 indicating a round hole, so that the positive and negative poles of the diode made can be evidently shown, and no wrong input of electric power will occur.

The drawings given is only for illustrating a preferred embodiment of present invention, it will be apparent to those skilled in this art that various modifications or changes without departing from the spirit of this invention such as changing of the shapes of the checks, the contact ends or the connecting legs etc. shall also fall within the scope of the appended claims.

1. A structure of a supporting frame, said supporting frame is made from an electric conductive metal sheet and has a plurality of continuous check like supporting units laid out in a plane, said check like supporting units are neighboring with other ones of said check like supporting units in vertical and horizontal directions, each of said check like supporting units has a peripheral frame, and has at a center thereof two separated semicircular contact ends which have a pair of connecting legs extending to said peripheral frame in mutual contrary directions; each of said peripheral frames of each of said check like supporting units is formed two cuts at two positions in middles of two frame edges in opposition to said connecting legs which extend to said peripheral frame;
said two semicircular contact ends are injection formed thereon an insulated seat, said insulated seat has two insulated supporting strips extending linearly therefrom to said two cuts in said middles of said two frame edges.

2. The structure of a supporting frame as claimed in claim 1, wherein said pair of connecting legs in each of said check like supporting units are different in shape.

3. The structure of a supporting frame as claimed in claim 1, wherein one of said pair of connecting legs in each of said check like supporting units has a mark.

4. The structure of a supporting frame as claimed in claim 3, wherein said mark of said connecting leg with said mark is a round hole.

5. The structure of a supporting frame as claimed in claim 1, wherein said check like supporting units are in rectangular shapes, said pair of connecting legs of each of said check like supporting units extend to shorter frame edges of corresponding one of said rectangular shapes from said two semicircular contact ends, said two cuts are provided on longer edges of said rectangular check like supporting unit.

6. The structure of a supporting frame as claimed in claim 1, wherein said two semicircular contact ends are provided thereon with a plurality of round holes.
